(19) United States
(12) Patent Application Publication
(10) Pub. No.: US 2011/0169445 A1
(43) Pub. Date: Jul. 14, 2011

(54) SOLAR-PANEL APPARATUS FOR A VEHICLE

(76) Inventor: Tsukasa SHIRAI, Toyohasi-si (JP)

(21) Appl. No.: 13/050,930

(22) Filed: Mar. 17, 2011

Related U.S. Application Data
(63) Continuation-in-part of application No. 11/845,636, filed on Aug. 27, 2007, now Pat. No. 7,944,169.
Application No. 11/845,636 is a continuation-in-part of application No. PCT/JP2006/304035, filed on Feb. 24, 2006.
Application No. PCT/JP2006/304035 is a continuation-in-part of application No. 11/400,133, filed on Apr. 10, 2006, now abandoned.

(30) Foreign Application Priority Data
Mar. 31, 2004 (JP) 2004-132209
Feb. 26, 2005 (JP) 2005-089737

(51) Int. Cl. H01L 31/05; H01M 10/46

(52) U.S. Cl. 320/101

(57) ABSTRACT

The positive and negative pole of the DC-battery 2-1 is allowed to be connected to the solar panel 2-11 and the solar panel 2-14 when the key position of the ignition switch 2-15 is in a position of “on” or “acc”. The positive and negative pole of the DC-battery 2-1 is not connected to the solar panel 2-11 and the solar panel 2-14 when the key position of the ignition switch 2-15 is in the position of “lock” or “start”. To attain such a configuration, lead wire connects the ignition switch 2-15 utilizing relay 2-4-a and fuse box 2-4-b. When the position of the ignition key is in “on” or “acc”, positive poles of the solar panels 2-11 and the solar panel 2-14 are connected to the positive pole of the DC battery 2-1 via the relay 2-4-a. Relays 3-4, 3-15, 3-16, 4-4, 4-15, and 4-16 have similar function as the relay 2-4-a.

### CROSS-REFERENCE TO RELATED APPLICATIONS

This application is a continuation-in-part of U.S. Utility patent application Ser. No. 11/845,636 filed on Aug. 27, 2007, now pending, which is a continuation-in-part of International PCT Patent Application No. PCT/JP2006/304035 filed on Feb. 24, 2006 and which is a continuation-in-part of U.S. Utility patent application Ser. No. 11/400,133 filed on Apr. 10, 2006. This application further claims priority benefits to Japanese Patent Application No. 2004-132209 filed on Mar. 31, 2004 and to Japanese Patent Application No. 2005-089737 filed on Feb. 26, 2005. The contents of the specifications of all of these applications are incorporated herein by reference for all purposes.

### BACKGROUND OF THE INVENTION

1. Field of the Invention

This invention relates to a solar panel apparatus for a motor vehicle which improves energy efficiency and battery lifetime, and can protect conductive parts and exterior coating of a vehicle from corrosion. In this invention, vehicle is defined to include all vehicles used on land, in or on the water, or in the air, such as an automobile, a boat, a vessel, and airplane.

2. Brief Description of the Related Arts

Japanese unexamined Utility Model Publication No. H02-79142 to Mikihiko Onda discloses a charging device comprising a battery, a solar panel on roof of an automobile for providing electricity for the battery, a dynamo-electric generator providing electricity for the battery, and a bypass circuit absorbs an overcharged electricity of the battery.

Japanese published unexamined patent application H07-316850 discloses the method of electric anticorrosion of the external power source system in which a solar battery provides anticorrosion current so that rust prevention can constantly be done at time zone such as nighttime.

The method of H07-316850 as the general method of the electric anticorrosion is comprised of seven elements in the FIG. 2 thereof. The elements are a solar panel, an electric cable from a positive pole of the solar panel to an anode plate, an insulator with this anode plate, water, a defended material against the corrosion, and an electric cable from the defended material against the corrosion to a negative pole of the solar panel.

In such conventional invention, improved fuel-efficiency is relatively low, a battery has low rates of life expectancy, and a coated surface of an exterior of a vehicle has a high affinity toward dust and dirt.

### SUMMARY OF THE INVENTION

Accordingly, the present invention has been made to solve the above-mentioned problems occurring in the prior art, and it is an object of the present invention to provide an electric supplemental apparatus for a vehicle, which can improve energy efficiency and lifetime of the battery, and can prevent conductive parts and exterior coating of a vehicle including an automobile, a boat, a vessel and an airplane from being corroded or deteriorated.

Another object of this invention is to improve the efficiency of an air conditioner for a vehicle.

To accomplish the above object, there is provided an electric supplemental apparatus for a vehicle comprising: an ignition switch for the vehicle; a battery for the vehicle; a solar panel being provided on the vehicle; and an electric circuit connecting the ignition switch, the battery and the solar panel; wherein the electric circuit connects the battery and the solar panel in the case when a key in the ignition switch is in positions of “on” or “acc”.

The ignition switch has positions for “LOCK”, “ACC”, “ON”, and “START”. Since the electricity is supplied from the solar panel to the battery, fuel efficiency is improved. Since the electric circuit connects the battery and the solar panel in the case that a key in the ignition switch is in position of “on” or “acc”, overcharge of electricity from the solar panel to the battery is prevented and lifetime of the battery is improved. In the position of “LOCK” or “START”, the electric circuit disconnects the battery and the solar panel.

Moreover, the decrease of the engine rotation occurs due to the electricity supplied from the solar panel, and as a result of it, tiredness of vehicle driving is decreased.

Electricity output of the solar panel is set to be between 0.05 W and 1 kW, preferably between 2 W and 1 kW for a compact car. The solar panel is installed at the top of the bonnet, the roof, or the trunk.

The upper size limit of the solar panel is set to a size which can be set on a vehicle. In consideration of durability of AC dynamo, the electric current value of the recharge electricity of the battery, the solar panel can cover the upper whole part of the vehicle without remodeling existing parts of the vehicle. A large-sized track loads can be equipped with a solar panel with the power rating above 1 kW.

In the case that the solar panel provides too much amount of electricity output to the battery, the existing devices of the vehicle need to be replaced by devices with a greater durability against high electric power, or the electric power needs to be decreased by control apparatus such as a shutter apparatus or a resistor or an on/off switch etc. When there is provided a plurality of solar panels, it is possible to decrease electric current by providing a countercurrent prevention circuit.

It is preferred that the electric circuit has a switch which sets the electric power input to the battery at least two steps.

It is possible to send a great deal of electric power to the vehicle battery from the solar panel, and it is also possible to send a little or no electricity supply to the vehicle battery from the solar panel, thereby prolonging the lifetime of the battery. A way of an electricity input by at least two steps from the solar panel to the vehicle battery is preferably attained by opening and shutting of a shutter apparatus which covers the solar panel.

The solar panel may include a first solar panel and a second solar panel that is smaller than the first solar panel, the first solar panel is connected to the battery when the key is in the position of “ON” or “ACC”, and the second solar panel is constantly connected to the battery.

A switch is provided between the battery and the solar panel so that a connection state is switched to an always-connection state between the battery and the solar panel before driving, when the key is not in the position of “ON” or “ACC”.

Since the connection state can be switched like this, the solar panel can powerfully charge to the DC-battery before vehicle start.

An on/off switch is provided between the battery and the solar panel so that all connection between the battery and the solar panel is cutoff in the case that an overcharge of the battery occurs during driving, stopping, and parking.

The on/off switch can cut the connection between the solar panel and the battery. The on/off switch is preferably installed at a place where a driver is able to operate from an operation seat. The on/off switch is preferably controlled by a microcomputer. With this on/off switch, the overcharge to the battery can be prevented. The generated electricity from the AC dynamo to the solar panel can fully be stopped. It is preferable that the on/off switch is provided in both of the wiring of the negative and positive poles of the solar panel.

The solar panel is provided with a switch for switching a supply state where electric output is supplied from the solar panel to the battery and a circulation state where a positive pole and a negative pole of the solar panel are connected to both ends of a body metal of the vehicle, respectively, so that the solar panel functions as an electric current circulation apparatus.

The solar panel has a first solar panel and a second solar panel such that the output of the second panel is lower than that of the first solar panel, an electric power which is generated at the second solar panel can be adjusted by a shutter apparatus which cover the second solar panel, or by a potentiometer or a combination of resistors which lowers the output of the second solar panel, and the second solar panel is in always-connection with the battery irrespective of the position of the key in the ignition switch, and the solar panel is smaller than the first solar panel.

This mechanism to charge the battery prevents the overcharge from the solar panel to the battery. Output of the second solar panel is preferably less than 0.6 W, more preferably between 0.01 and 0.3 W.

In additional embodiments, provided is an electric supplemental apparatus for a vehicle comprising: a battery for the vehicle; a solar panel being provided on the vehicle; a shutter apparatus for covering the solar panel so that light input into the panel is adjusted; and an electric circuit connecting the battery and the solar panel; and potentiometer, a resistor, or an on/off switch, or a combination thereof which lowers the output of the solar panel to the battery.

In additional embodiments, provided is an electric supplemental apparatus for a vehicle comprising: a battery for the vehicle; a solar panel being provided on the vehicle; and an electric circuit connecting the battery and the solar panel; wherein both ends of a body metal of the vehicle are connected to a positive pole and a negative pole of the solar panel, respectively, so as to circulate electrical current through the body metal.

It is preferable that a switch is provided for switching a first state where the solar panel is connected to the battery to charge the battery, and a second state where electricity is circulated through the body metal by the solar panel. The coated surface of the vehicle receives the circulation and discharge of the electricity so that the anticorrosion phenomenon of the vehicle and the effective functioning of the vehicle body are attained.

### BRIEF DESCRIPTION OF THE DRAWINGS

FIG. 1 is a perspective view of a solar apparatus according to the invention;

FIG. 2 is a block schematic diagram of a first embodiment of this invention;

FIG. 3 is a block schematic diagram of a second embodiment of this invention;

FIG. 4 is a block schematic diagram of a third embodiment of this invention;

FIG. 5 is a perspective view of a shutter apparatus according to this invention;

FIG. 6 is a perspective view of an apparatus of a fourth embodiment of this invention.

FIG. 7 is a perspective view of a fifth embodiment of this invention;

FIG. 8 is a perspective view of a shutter apparatus of this invention;

FIG. 9 is a block schematic diagram of a sixth embodiment of this invention;

FIG. 10 is a block schematic diagram of a seventh embodiment of this invention;

FIG. 11 is a block schematic diagram of an eighth embodiment of this invention;

FIG. 12 is a block schematic diagram of a ninth embodiment of this invention;

FIG. 13 is a block schematic diagram of a tenth embodiment of this invention;

FIG. 14 is a block schematic diagram of an eleventh embodiment of this invention;

FIG. 15 is a block schematic diagram of a twelfth embodiment of this invention;

FIG. 16 is a block schematic diagram of a thirteenth embodiment of this invention; and

FIG. 17 is an illustration of the structure of an ignition switch (an Ignition key cylinder) of commonly used type having the positions of “LOCK, ACC, ON, START”.

FIG. 18 is a modified version of the embodiment shown in FIG. 6.

FIG. 19 is another modified version of the embodiment shown in FIG. 6.

FIG. 20 is another modified version of the embodiment shown in FIG. 6.

FIG. 21 is another modified version of the embodiment shown in FIG. 6.

FIG. 22 is another modified version of the embodiment shown in FIG. 6.

### DETAILED DESCRIPTION OF THE INVENTION

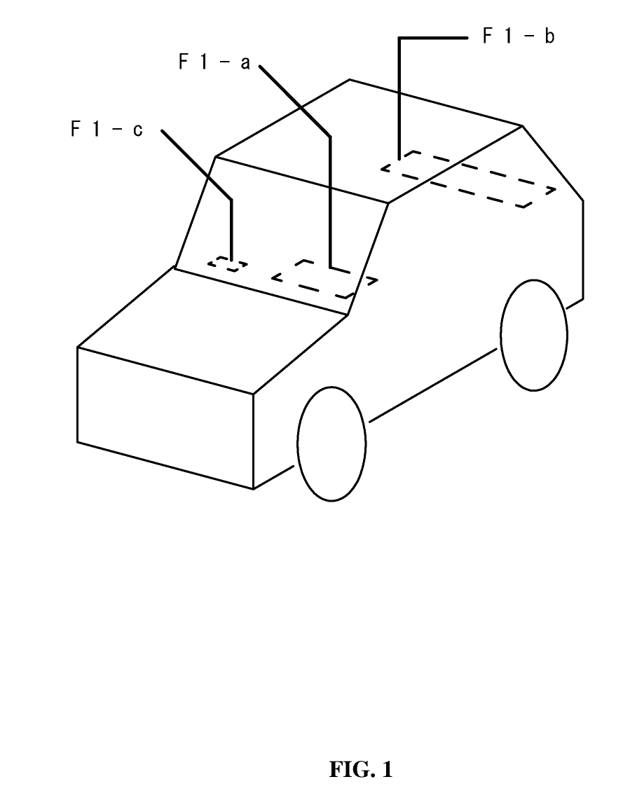

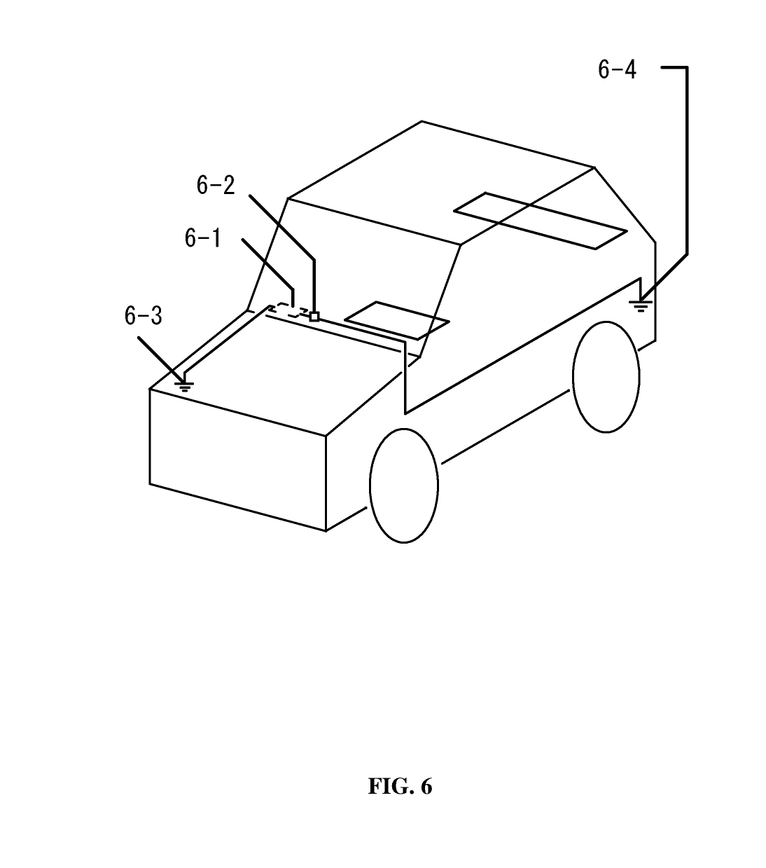

Hereinafter, with reference to FIGS. 1-22, the structure of an electric supplemental apparatus for a vehicle will be described in detail. Explanation will be made taking an automobile as an example; however, the apparatus explained below can be applicable to all vehicles used on the land, on and in the water, and in the air, such as an automobile, a boat, a vessel and an airplane. FIG. 1 shows the appearance of the automobile provided with a front solar apparatus F1-a, a rear solar apparatus F1-b, and a solar apparatus F1-c for an anticorrosion system. In order to utilize sunlight in addition to a gasoline or diesel oil, etc, the front solar apparatus F1-a is provided with a solar panel on the inner place of a dashboard of an automobile, the rear solar apparatus F1-b is provided with a solar panel on the inner place of a rear part of the automobile, and the solar apparatus F1-c is provided with a solar panel on the inner place of a dashboard of an automobile. As shown in FIG. 6, the solar panel F1-c, which corresponds to 6-1 in FIG. 6, generates electricity to circulate electricity through the automobile metal body while the solar panels F1-a and F1-b generate electricity to charge the battery.

The solar panel apparatuses F1-a and F1-b are installed inside the automobile to avoid visually undesirable appearance, short life time, necessity of being waterproof, high cost, and complicated structure. The solar panel apparatus F1-a and F1-b are provided near the window because of fuel consumption improvement, the driving stability, and light-receiving stability.

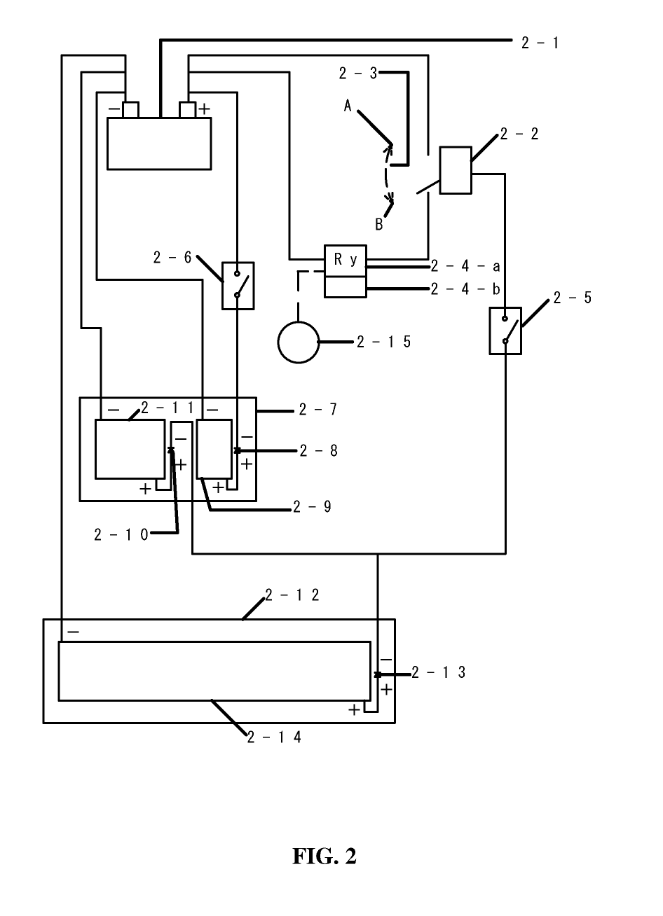

Hereinafter, referring to FIG. 2, a first embodiment of an electric supplemental apparatus for a vehicle will be described in detail. In FIG. 2, the DC-battery 2-1 is a GS BATTERY of JIS 38B19 made by GS Yuasa Battery Ltd. in Japan. The maximum size is, e.g., length 187 mm, width 127 mm, and height 203 mm (overall height 227 mm). A positive pole of a DC-battery 2-1 is connected to a toggle switch 2-2. The toggle switch 2-2 can be changed over as shown by reference numeral 2-3. At a B position of the toggle switch 2-2, the positive pole of the DC-battery 2-1 is connected to the toggle switch 2-2 via a relay 2-4a with a fuse 2-4b to which an ignition switch 2-15, so called Ignition key cylinder, is connected. At the A position of the toggle switch 2-2, the positive pole of the DC-battery 2-1 is connected to the toggle switch 2-2 without the relay 2-4a and the fuse 2-4b. The toggle switch 2-2 is connected to a semiconductor diode 2-10 via an on/off switch 2-5, and to a semiconductor diode 2-13 via the on/off switch 2-5, respectively. The positive pole of the DC-battery 2-1 is connected to a semiconductor diode 2-8 via an on/off switch 2-6. The diode 2-8 is connected to a solar panel 2-9. A front solar apparatus 2-7 comprises the diode 2-8, the solar panel 2-9, the diode 2-10, and a solar panel 2-11. A rear solar apparatus 2-12 comprises a diode 2-13 and a solar panel 2-14. A negative pole of the DC-battery 2-1 is connected to negative poles of the solar panel 2-9, the solar panel 2-11 and the solar panel 2-14, respectively.

The solar apparatus 2-7 is placed on the dashboard of the automobile and the solar apparatus 2-12 is placed in the rear part of the automobile. The boards for placing the solar panels 2-9, 2-11 and 2-14, and the diodes 2-8, 2-10, and 2-13 are, preferably, made of a material which is non-conductive (for example plastics), is not deformed by daylight, and is flame-retardant. The dimension of the apparatus 2-7 is 200 mm wide by 341 mm long, and between 4 mm and 13 mm in thickness. The dimension of the apparatus 2-12 is 200 mm wide by 680 mm long, and between 4 mm and 13 mm in thickness.

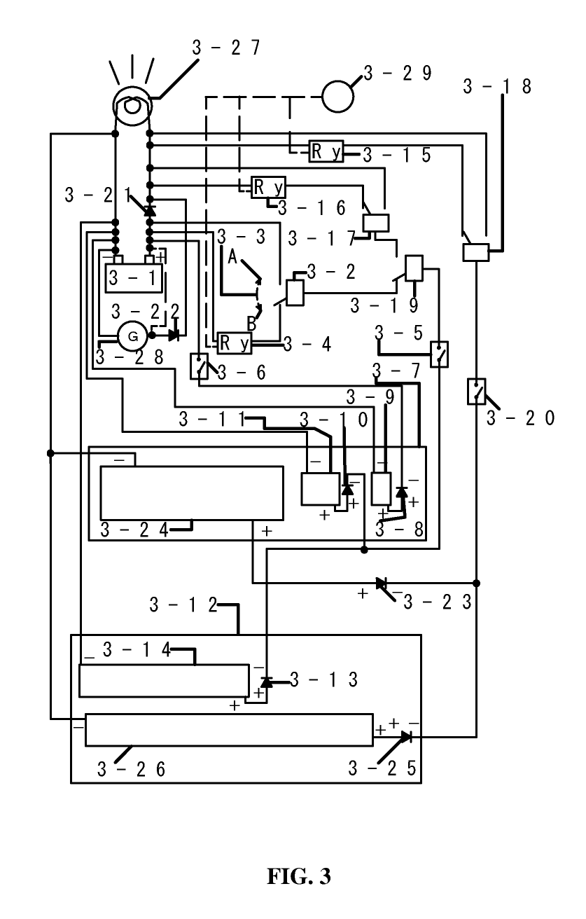

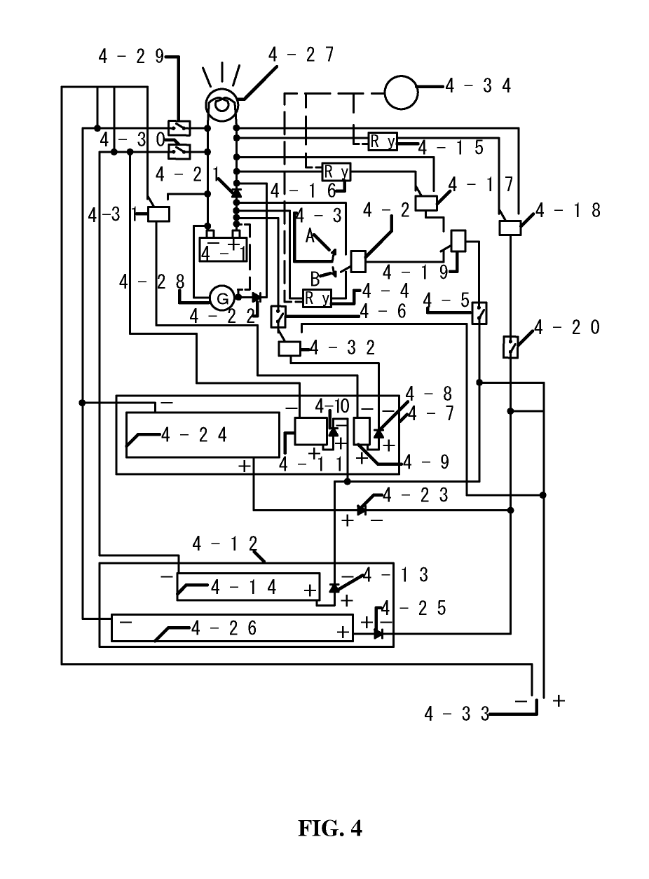

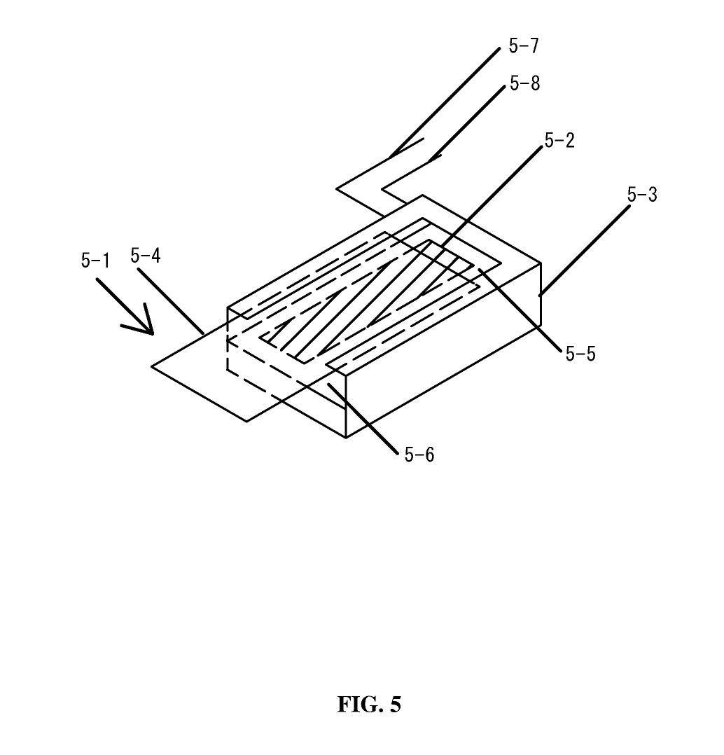

As shown in FIG. 2, the solar panel 2-9 is constantly connected to the DC-battery 2-1 with voltage 15 V, current intensity 0.02 A, and power of 0.3 W, unless a switch 2-6 is off. The panels 2-11 and 2-14 are not constantly connected to the DC-battery 2-1. The panel 2-9 is smaller than the panel 2-11, and the panel 2-11 is smaller than the panel 2-14. The size of the panel 2-9 is preferably set smaller than 15 mm in length and 30 mm in width. The panel 2-9 is provided with a shutter apparatus 5-1 as shown in FIG. 5. A solar panel 3-9 and a solar panel 4-9 as shown in FIGS. 3 and 4 are also provided with the shutter apparatus 5-1. The shutter apparatus 5-1 controls the amount of light received by the solar panels 2-9, 3-9, and 4-9 installed therein. The diode 2-8 having a maximum rating of 30 V and 0.45 A prevents electric current to flow from the battery 2-1 to the solar panel 2-9. All semiconductor diodes shown in FIGS. 2, 3, and 4 have the same function as the diode 2-8.

Due to the diode 2-8, which prevents reverse current, and the shutter apparatus 5-1, which suppresses the charge of the battery 2-1 by the solar panel 2-9, battery life is prolonged, and the cost and the effort of DC-battery exchange decrease generally. Taking a use of long term of more than half or one year into consideration, it is more user-friendly to decrease the effort of exchanging DC-batteries by restricting the amount of light received by the solar panel 2-9 to some extent. Such a configuration of the solar panel of always-connection is set not only in the 1st embodiment but also in the 2nd embodiment and the 3rd embodiment. While running, the on/off switch 2-6 is switched off by the driver in the case of overcharge of the battery 2-1 due to input from an AC dynamo and the solar panel 2-9. The switch 2-6 is installed in the place near a driver's seat suitable for operating the switch 2-6. For the same purpose, the on/off switches 2-5, 3-5, 3-6, 3-20, 4-5, 4-6, and 4-20 are also installed in the place near the driver's seat.

As shown in FIG. 2, during daytime operation of automobile, the solar panel 2-11 outputs 14 V, 0.4 A, and 5.6 W and the solar panel 2-14 outputs 15 V, 0.07 A, and 1.05 W. The solar panel 2-11 is connected to the diode 2-10 of maximum rating of 40 V and 3 A with an anti-reverse current function. The solar panel 2-14 is connected to the diode 2-13 having a maximum rating of 40 V and 5 A with an anti-reverse current function.

The positive and negative poles of the DC-battery 2-1 are allowed to be connected to the solar panel 2-11 and the solar panel 2-14 when the key position of the ignition switch 2-15 is in the position of “on” or “acc”. The positive and negative pole of the DC-battery 2-1 is not connected to the solar panel 2-11 and the solar panel 2-14 when the key position of the ignition switch 2-15 is in the position of “lock” or “start”. To attain such a configuration, lead wire connects the ignition switch 2-15 utilizing relay 2-4-a and fuse box 2-4-b. Relays 3-4, 3-15, 3-16, 4-4, 4-15, and 4-16 shown in FIG. 3 and FIG. 4 are substantially the same in function and capabilities as the relay 2-4-a, and the fuse 2-4-b. When the position of the ignition key is in “on” or “acc”, positive pole of the solar panels 2-11 and the solar panel 2-14 are connected to the positive pole of the DC battery 2-1 via the relay 2-4-a. Relays 3-4, 3-15, 3-16, 4-4, 4-15, and 4-16 are similar to the relay 2-4-a.

Toggle switch 2-2 is switched from a position A to a position B, or vice versa as shown in the direction 2-3. In FIG. 2, the toggle switch 2-2 is connected to the relay 2-4-a and fuse 2-4-b at the position B. This connection is made at the time of automobile driving with the above-mentioned key positions of “ON” or “ACC”. In case the that the toggle switch 2-2 is turned to the position A, the solar panel 2-11 and 2-14 are always connected to the positive pole of the DC battery 2-1, unless a on/off switch 2-5 is off. The connection between the solar panel 2-9 and the battery 2-1 means an always-on connection. When the automobile is not in use, the toggle switch 2-2 should be set to position B. At this time, the electricity from the solar panel 2-11 and the solar panel 2-14 is not inputted. When the automobile is driven, it does not make any difference whether position A or B is selected. The electrical input from the solar panel 2-11 and the solar panel 2-14 are accepted at that time. As a way of riding with good fuel efficiency, for example, the switch 2-2 may be turned to position A 5 minutes before starting to charge the DC battery 2-1 from the solar panels 2-11 and 2-14, and the switch 2-2 may be turned to the position B when arriving at a destination and the engine is stopped. As another user-friendly way of riding, neither the toggle switch nor the on/off switch is operated with the switch 2-2 being at the position B. The electricity is input to the battery 2-1 from the solar panels 2-11 and 2-14 during “on” or “acc” position of the ignition switch 2-15. Those who do not know the system of this automobile could also drive this automobile freely, and fuel consumption is also able to be ameliorated. The switch 2-2 is installed near the on/off switches 2-5 and 2-6, and the driver can operate the switch 2-2 from the driver's seat.

FIG. 3 shows a solar apparatus of a second embodiment which is similar to the apparatus of the first embodiment of FIG. 2. Hereinafter, differences between the apparatus of FIGS. 2 and 3 will be described. According to the 2nd embodiment shown in FIG. 3, the solar panel apparatus 3-7, and 3-12 are placed separately inside the vehicle near the front and the rear window panes, respectively, in the same way as in the arrangement of the solar apparatuses 2-7 and 2-12 of the 1st embodiment, but this 2nd embodiment features a different size and different number of pieces of the solar panels, and is designed so as to enlarge the size.

The all time connection, “always-on connection”, is made with respect to the first solar panel 3-9 with 15V, 0.02 A, 0.3 W, small output in the daytime, and only the panel 3-9 has a light input control shutter plate (a stepless generated power modification controller with a shutter plate) which is shown in FIG. 5. A first semiconductor diode 3-8 of maximum rating 30V, and 0.45 A, prevents electric current to flow from the battery 3-1 of a 38B19 model DC-battery to the solar panel 3-9. The diode 3-8 prevents the DC-battery 3-1 being electrically opened, and current passing inside the solar panel in the reverse direction. The meaning of the wiring of the diode 3-8 and a stepless light input control shutter 5-1 of FIG. 5 has been described in the first embodiment. During running, power is stably inputted from an AC dynamo, and also inputted from the solar panel 3-7. The on/off switch 3-6 can be turned off manually by the driver to prevent overcharging.

The second solar panel 3-11 outputs 15V, 0.07 A, and 1.05 W, during daytime. The third solar panel 3-14 outputs 14 V, 0.4 A, and 5.6 W during daytime. The fourth solar panel 3-24 outputs 14 V, 0.85 A, and 11.9 W during daytime. The fifth solar panel 3-26 outputs 14 V, 1.0 A, and 14 W during daytime. The second solar panel 3-11 is accompanied by the second semiconductor diode 3-10 having a maximum rating of 40 V and 3 A for preventing reverse current. The solar panel 3-14 is accompanied by the semiconductor diode 3-13 having a maximum rating of 40 V and 5 A for preventing a reverse current. The solar panel 3-24 is accompanied by the semiconductor diode 3-23 having a maximum rating of 100 V and 3 A for preventing reverse current. The solar panel 3-26 is accompanied by the semiconductor diode 3-25 having a maximum rating of 100 V and 3 A for preventing a reverse current.

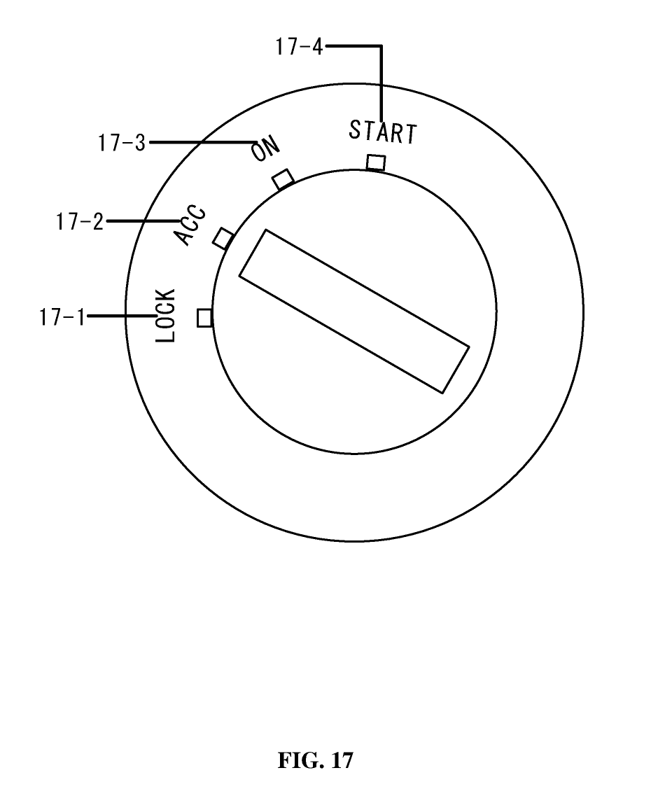

In order that the solar panels 3-11, 3-14, 3-24, and 3-26 are connected only when the automobile is used as solar panels with “connection at the time of automobile use”, an ignition switch 17 as shown in FIG. 17 and relays 3-4, 3-15, 3-16 are used. When the key of the automobile is twisted in ignition, the solar panels 3-11, 3-14, 3-24, and 3-26 are connected to positive pole of the DC-battery 3-1 in the case of the position “on” or “acc”, and are not connected to the positive pole of the DC-battery 3-1 in the case of the position of “lock” or “start.” For example, fuses connected to the relays allow the connection only in the case of “on” or “acc” when ignition is twisted. (The ignition switch 3-29.) Relays 3-4, 3-15, 3-16 allow the connection at the time of automobile use which means the case the key is at “on” and “acc”.

Toggle switches 3-2, 3-17 and 3-18 with a switch tongue can choose either the position for “always-on connection” as shown in position A where the circuit does not have a relay, or the position for “connect at the time of automobile use” as shown in position B with a circuit with a relay. Reference number 3-3 denotes the changeover of the switch tongue. The switch 3-2 can be switched to the position B with the circuit with the relay 3-4. In the case the switch 3-2 is switched to position A, the solar panels are always connected to the positive pole of battery 3-1.

The toggle switches 3-17 and 3-18 have a similar function as the switch 3-2. Toggle switches are switched over to position B with a relay circuit during non-use of the automobile. The reason for this has been stated. The tongues of the toggle switches are put in a place where the driver can operate it from the driver's seat. They are installed near the tongue group of the on/off switches. The driver can change the positions of the tongues of the toggle switches freely. The reason or this has been described.

The specification of the 2nd embodiment differs from that of the 1st embodiment in that the semiconductor diodes 3-21 and 3-22 having a maximum rating of 200 V and 60 A are provided to prevent charging the DC battery 3-1 by the solar panels 3-24 and 3-26. For a further enlargement of the solar panels, the diode 3-21 and 3-22 are attached in order to prevent much electrical input to the DC-battery from the solar panels. Too much overcharge of the DC-battery is undesirable. Measures for preventing overcharge of the DC-battery 3-1 should be first taken into consideration when high power is generated in the 2nd embodiment of FIG. 3. Generated power by the solar panels is much larger than that of the 1st embodiment due to the solar panel 3-24 of 4 14 V, 0.85 A, and 11.9 W output and the solar panel 3-26 of 5 14 V, 1.0 A, and 14 W output. In order to prevent much input of generated electric power into the DC-battery 3-1, the semiconductor diodes 3-21 and 3-22 are attached. The dotted line, which connects the AC dynamo 3-28 and the DC-battery 3-1, means the connection between the positive poles of both of them.

The toggle switch 3-19 shown in FIG. 3 is provided for the strong sunlight of a season such as summer. In such a season, the switch 3-19 is switched to another position from the position shown in FIG. 3 so as not to supply the generated electric power by the solar panels 3-11 and 3-14 to the DC-battery 3-1. The position shown in FIG. 3 allows the generated electric power by standard or weak sunlight to be output from the panels 3-11 and 3-14 and to be input to the DC-battery 3-1. The reference numeral 3-27 denotes a light as an example of electrical or electronic apparatus.

According to the 3rd embodiment of FIG. 4, the solar panel apparatuses 4-7 and 4-12 are separately placed generally inside the vehicle near the front and the rear windowpanes, respectively and have fundamentally the same structure as the apparatuses 2-7 and 2-12 of the 1st embodiment. Not all of the panels might be installed inside the automobile due to the enlargement of the panels as compared with the 2nd embodiment. Part of the solar panels may be installed outside the automobile, such as on a roof. The solar panels 4-24 and 4-26 may be divided to be placed on inside and outside of the automobile.

FIG. 4 shows a solar apparatus of a third embodiment which is similar to the apparatus of the second embodiment of FIG. 3. Hereinafter, differences between the apparatus of FIGS. 3 and 4 will be mainly described. In FIG. 4, the all time connection, “always-on connection”, is made with respect to the solar panel 4-9 with 15 V, 0.02 A, and 0.3 W of small output in the daytime, and this panel 4-9 has a light input control shutter plate, a stepless generated power modification controller with a shutter plate as shown in FIG. 5. The semiconductor diode 4-8 having a maximum rating of 30V and 0.45 A prevents current flow from the battery 4-1 to the solar panel 4-9. The diode prevents the DC-battery 4-1 being electrically opened, and current passing inside the solar panel 4-9 in the reverse direction. The meaning of the wiring of the diode 4-8 and a stepless light input control shutter 5-1 of FIG. 5 has been mentioned. During running, power is stably inputted from an AC dynamo, and also inputted from the solar panel 4-9. The on/off switch 4-6 can be turned off manually by the driver to prevent an overcharge of the power.

The solar panel 4-11 outputs 15V, 0.07 A, and 1.05 W during daytime. The solar panel 4-14 outputs 14 V, 0.4 A, and 5.6 W during daytime. The solar panel 4-24 outputs more power than the panel 3-24 of the 2nd embodiment of FIG. 3, with 14 V, 0.85 A, and 11.9 W. The solar panel 4-26 outputs more than the panel 3-26 of the 2nd embodiment of FIG. 3, with 14 V, 1.0 A, and 14 W. The solar panel 4-11 is accompanied by the semiconductor diode 4-10 having a maximum rating of 40 V and 3 A for preventing reverse current. The solar panel 4-14 is accompanied by the semiconductor diode 4-13 having a maximum rating of 40 V and 5 A for preventing reverse current. The solar panel 4-24 is accompanied by the semiconductor diode 4-23 which has a maximum rating of the electrical voltage and current being three or more times high as the electrical voltage and current which the solar panel 4-24 outputs for preventing reverse current. The solar panel 4-26 is accompanied by the semiconductor diode 4-25 which has a maximum rating of the electrical voltage and current being three or more high as the electrical voltage and current which the solar panel 4-26 outputs for preventing reverse current.

In order that the solar panels 4-11, 4-14, 4-24, and 4-26 are connected only when the automobile is used, an ignition switch and a relay function are used. That is, current flows to the positive pole of a DC-battery only when the key of an automobile is twisted in the ignition switch and is set at “on” or “acc”, and current does not flow when the key is set at “lock” or “start.” This wiring can be made by connecting fuses to relays which allow conduction with the positive pole of the DC-battery only when the ignition key is twisted and is set at “on” or “acc”. In the 3rd embodiment, relays 4-4, 4-15, and 4-16 have the same function as mentioned above, and connection is made when the automobile is used and the key in the ignition switch 4-34 is set at “on” or “acc”.

The toggle switches 4-2, 4-17, and 4-18 can choose electric flow between “always-on connection” of position A where the circuit does not have a relay, and “connection at the time of automobile use” of position B with a relay with a circuit with a relay. It is shown that wiring changes if the tongue of the toggle switch 4-3 is moved. In “FIG. 4”, the toggle switch 4-2 is illustrated as being set at the position B connecting the relay 4-4. If the tongue of the toggle switch 4-2 is moved and is set at position A, the solar panels will be connected to the positive pole of a DC-battery 4-1 without the relay 4-4, and thus will always be connected. The position A connection means “always-on connection.” The position B connection means “connection at the time of automobile use.” The concept of how to switch the toggle switches 4-2, 4-17, 4-18 between “always-on connection” of the position A without a relay and “connection at the time of automobile use” of position B with a relay is the same, and when not riding in an automobile, the toggle switch is surely moved in the direction of position B with a relay circuit. The reason for this has been described. The tongue of a toggle switch itself was put in a place where it can be operated from the driver's seat, and it was installed near the tongue group of the on/off switches. A driver may switch the tongue of a toggle switch freely as he/she desires when the driver of the automobile understands the mechanism.

FIG. 4 (the 3rd embodiment) and FIG. 2 (the 1st embodiment) differ notably in that the 3rd embodiment features attached semiconductor diodes 4-21 and 4-22 having a maximum rating of 200 V and 60 A, and a maximum rating of 200 V and 60 A, respectively. Due to further enlargement of connected solar panels for “connection at the time of automobile use”, these were attached in order not to permit a large amount of electrical input to the DC-battery from the solar panels. A DC-battery does not desire too much overcharge. Moreover, putting it in another way, measures against overcharge of the DC battery 4-1 should be first taken into consideration when a big electric power is generated in the apparatus of the 3rd embodiment shown in FIG. 4. In the 3rd embodiment, power of the solar panel generator of the solar panel No. 4 4-24 and solar panel No. 5 4-26 are larger compared to the 1^{st} embodiment. Semiconductor diode 4-21 and 4-22 are attached in order not to make generated electric power input into the DC-battery 4-1. The dotted line, which connects the AC dynamo 4-28 and the DC-battery 4-1, means the connection of the positive poles of both of them.

The toggle switch 4-19 of FIG. 4 is similar to that of FIG. 3. This toggle switch was prepared for the seasons with strong sunlight, such as summer, in order to prevent the generated electric power of the solar panels 4-11 and 4-14 from being inputted into the DC-battery by changing the position of the switch to the side where the DC-battery is not connected. The overcharge to a DC-battery is thus avoided. The state of connection of FIG. 4 making the generated electric power of panels 4-11 and 4-14 input into the DC-battery 4-1 is a setup for weak sunlight.

In some cases, user would like to cut a connection between the solar panel and the automobile, and use the electric power of the solar panel for a notebook computer used in the automobile or electric appliances used outdoor by connecting a code to the solar panels and taking electricity from the solar panel. An output terminal 4-33 is taken out from the wiring connecting the battery 4-1 and the panels for this purpose. The voltage of the terminal 4-33 is set to DC 12V or more. The user can increase the voltage from DC 12V to AC 100V by using the converter which is sold at a low price at local stores. In consideration of possibility that an unstable element will be generated with respect to the electricity which flows to and from the automobile, the on/off switch 4-29 and 4-30 are attached in order to cut the unstable element. Toggle switches 4-31 and 4-32 are also provided to cut the unstable element by the electricity with the automobile, and are set to change between “always-on connection with a DC-battery”, and “the power source for the exteriors which is independent of the automobile”.

FIG. 5 shows a shutter apparatus 5-1 in which a solar panel 5-2 is installed. The solar panel 5-2 is selected from either one of the solar panels 2-9, 3-9, and 4-9. The shutter apparatus 5-1 comprises a container 5-3, a shutter plate 5-4, a gap 5-5, a slot 5-6, a lead wire 5-7 and 5-8. Light input can be adjusted by sliding the shutter plate 5-3 in longitudinal direction to change width of the gap 5-5. Light passes through a gap so that the light reaches the solar panel 5-2. The shutter plate 5-4 consists of lightproof material. The container 5-3 holds the shutter plate 5-4 at the upper portion such that the plate 5-4 can slide. An additional shutter (not shown), such as patterned ground-glass plate, blue transparent plate or transparent plate of various colors, may be provided above or under the plate 5-4. The additional plate is taken in and out under the shutter plate 5-4. Variable effect can be enjoyed. The gap 5-5 is basically narrow in this embodiment. Lead wire 5-7 is connected to the negative pole of the DC-battery with parallel connection. Lead wire 5-8 is connected to the positive pole of the DC-battery with parallel connection.

FIG. 6 shows a solar apparatus of a fourth embodiment. FIG. 6 shows the apparatus F1-c of FIG. 1. While a solar panel 6-1 of the “always-on connection” generates electricity, electricity circulates between the grounding points 6-3 and 6-4 which are connected respectively to the body ends of the automobile and thus circulates in the automobile body and parts between them. The solar panel 6-1 is provided for the purpose of electrically preventing corrosion.

The maximum output of the solar panel 6-1 is between 14 V, 3 A and 0.25 V, 0.03 A, i.e., at values at which electricity does not usually have an effect on the human body and does not cause fire.

An on/off switch 6-2 is connected to the panel 6-1 and the ground 6-4. The driver can operate the on/off switch 6-2 to stop the flow of electricity if he/she desires. A reason why a semiconductor diode is not installed in this circuit is that it may make the driver feel unpleasant. According to the apparatus of FIG. 6, electricity flows in the automobile metal body on which an anticorrosive coat is deposited, thereby exhibiting an electric anticorrosion phenomenon, the reduction of the dirt adhesion to the automobile and automobile parts, the effect of making the automobile body protection agent coated on the automobile body be more powerful, with more long life time, and with increased gloss. The apparatus of FIG. 6 cannot directly contribute to the improvement of the mileage. However, according to the above-mentioned structure, electric resistance of the automobile body becomes relatively low due to reduced dirt or corrosion on the automobile, and thus firing of the sparking plug becomes cleaner and stronger in the gasoline engine automobile thereby contributing to the improvement of the mileage indirectly.

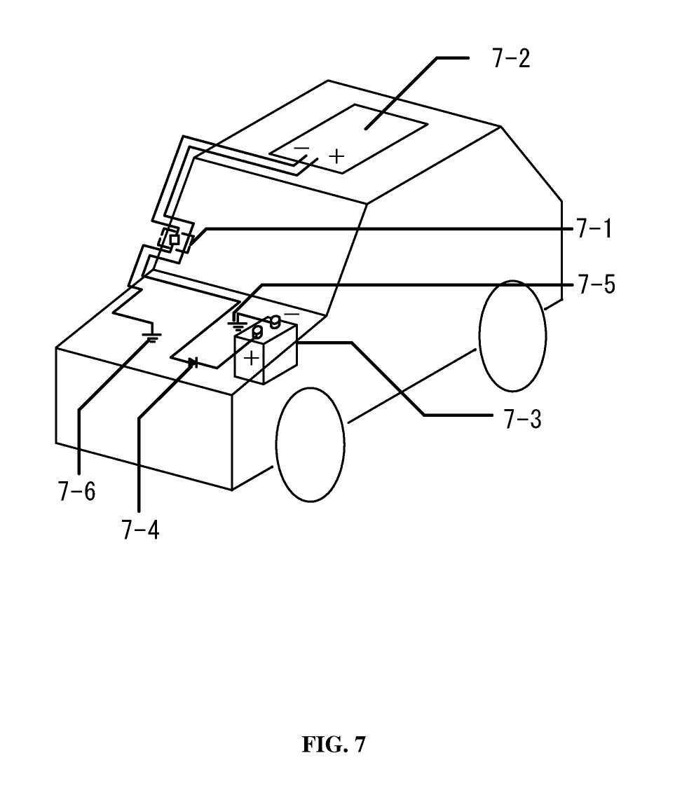

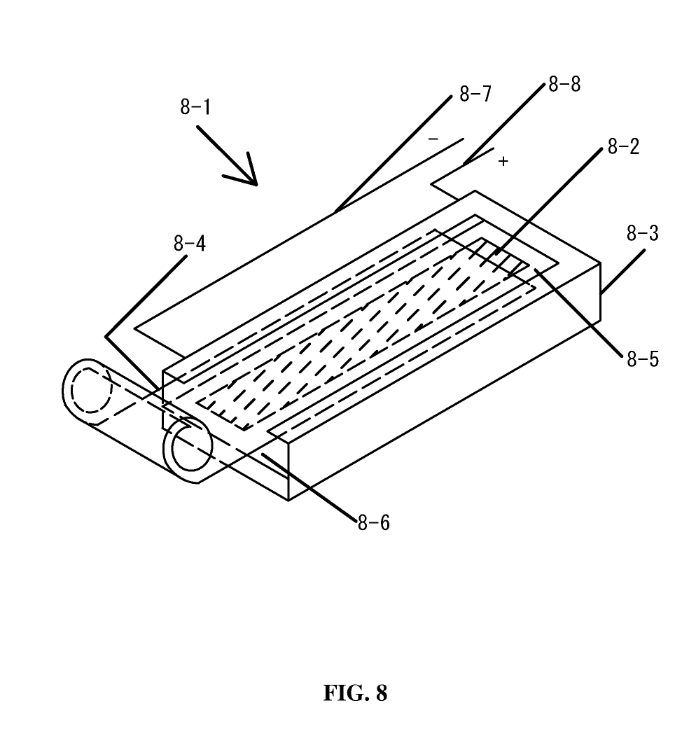

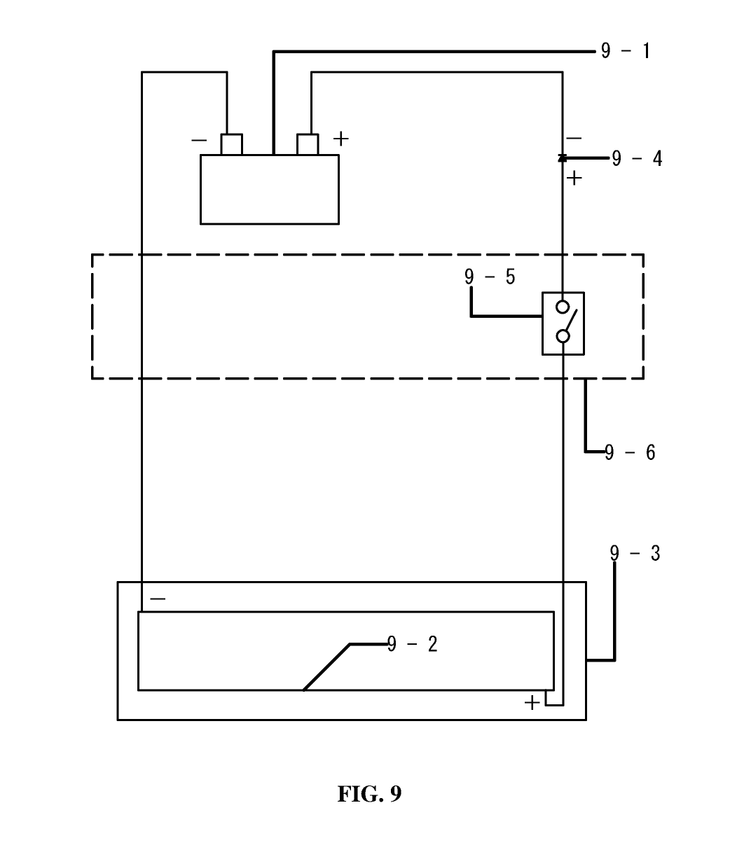

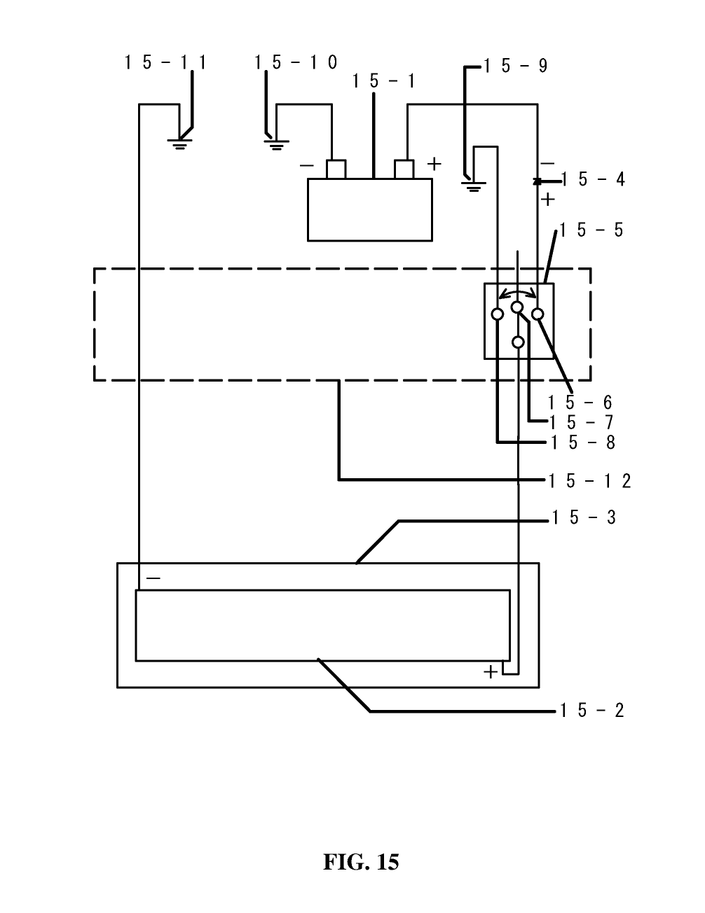

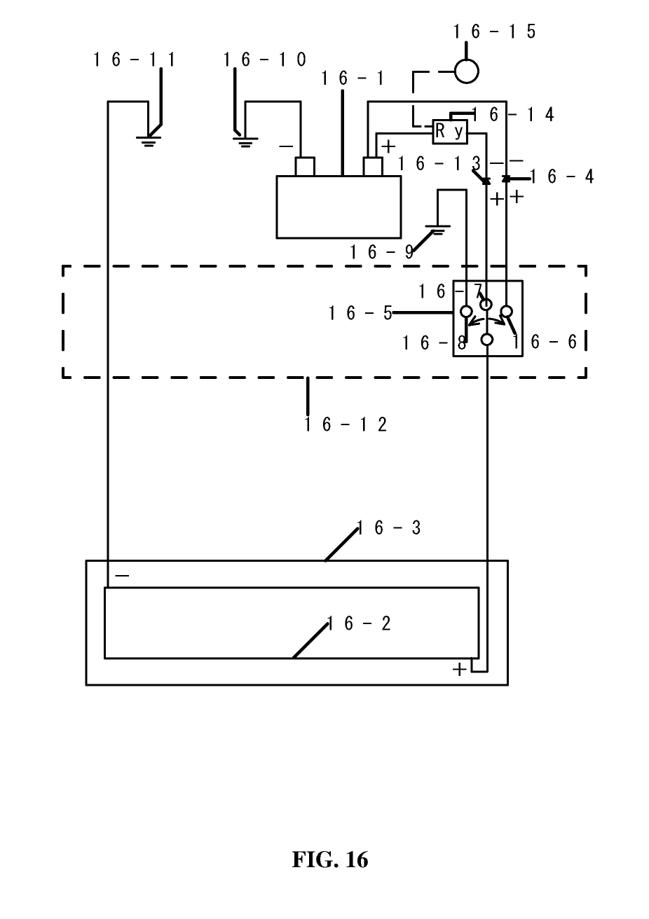

FIG. 7 shows a solar apparatus of a fifth embodiment which is similar to the apparatus of the fourth embodiment of FIG. 6. Hereinafter, differences between the apparatus of FIGS. 6 and 7 will be mainly described. FIG. 7 shows an apparatus with the electric output from a solar panel 7-2 by means of equal to or more than two steps. The part 7-1 surrounded by the square dotted line includes a switch and wiring. The parts 9-6, 10-9, 11-7, 12-8, 13-13, 14-12 have similar functions to the part 7-1. Switches and wiring are changed in the respective figures. Wiring is drawn into the interior of the automobile for the driver to touch the switch from inside the automobile. The large size or the medium size solar panel 7-2 is connected to the automobile battery 7-3 in parallel connection through the circuit 7-1 and a semiconductor diode 7-4 which is the countercurrent prevention circuit by a semiconductor such as Schottky diode. The semiconductor diode 7-4 may be replaced by a circuit including an operational amplifier and the like with a lower heat generation. The electricity supplied from the panel 7-2 to the battery 7-3 can be cut off by operating the switch of the circuit 7-1. The output of the panel 7-2 can be controlled by the shutter apparatus as shown in FIG. 8 in which the panel 7-2 is installed so as to decrease electric power. A negative terminal of the battery 7-3 is connected to a ground 7-5. A negative pole of the panel 7-2 is connected to a ground 7-6 via the circuit 7-1. The negative pole from the solar panel 7-2 may be connected to the negative pole of the battery 7-3 as shown in FIGS. 9-14, or may be connected to the cylinder head of a gasoline engine. The ground 15-9-15-11 of FIG. 15 and the ground 16-9-16-11 of FIG. 16 have similar functions as the ground 7-5 and 7-6 of FIG. 7. In FIGS. 9, 10, 11, 12, 13, and 14, the balance with the resistance value of the resistors must be considered.

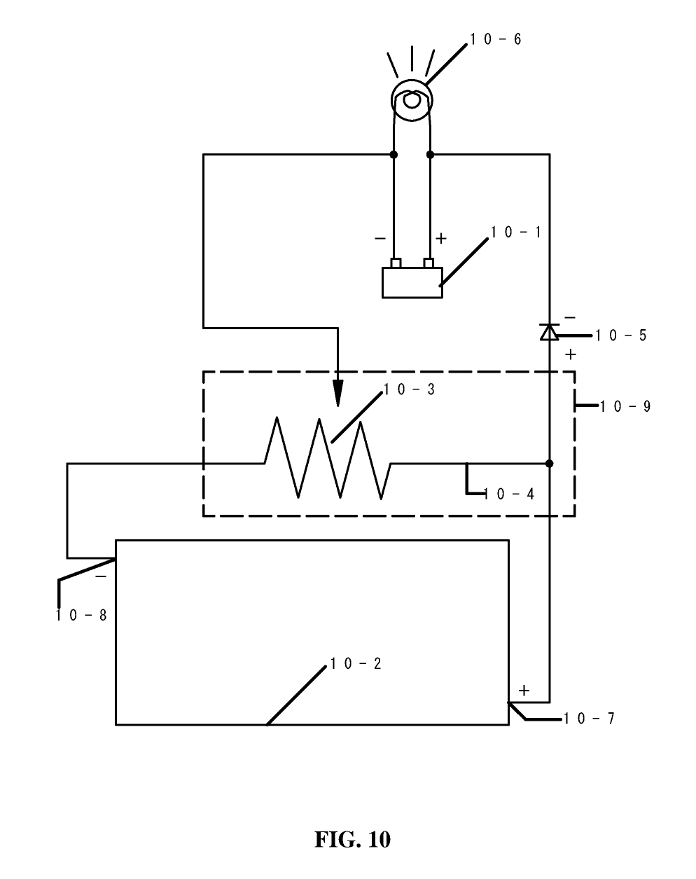

FIG. 8 shows a shutter apparatus 8-1 which is similar to the shutter of FIG. 5, and so, hereinafter, differences between the shutter 5-1 and the shutter 8-1 will be mainly described. The shutter plate 8-4 of the metal or cloth and so on can be bended or rolled up at a longitudinal end for compact size. The shutter apparatus 8-1 can cover the solar panels as shown in FIGS. 9-16, and preferably used to the solar panels as shown in FIGS. 9, 15 and 16. In FIGS. 10-14, it is possible to lower the electricity input by wiring without shutter apparatus 8-1. In FIG. 9, there is provided an on/off switch 9-5, and in FIGS. 15 and 16, there is provided a toggle switch. The apparatus as shown in FIG. 9 can be used without the shutter apparatus 8-1 because there is provided with an on/off switch 9-5. The apparatus as shown in FIGS. 15 and 16 can be used without the shutter apparatus 8-1 because there is provided toggle switches. The apparatus as shown in FIG. 9 can be used with the shutter apparatus 8-1 even if a switch 9-5 is deleted and the solar panel 9-2 and a diode 9-4 are connected directly. In such a case, the shutter apparatus 8-1 is necessary to avoid overcharge of the battery.

According to FIG. 9 of a solar apparatus of a sixth embodiment, a positive pole of a solar panel 9-2 is connected to a positive pole of a DC battery 9-1 via a diode 9-4 and an on/off switch 9-5. A negative pole of the solar panel 9-2 is connected to a negative pole of the DC battery 9-1. The diode 9-4 has a countercurrent prevention function by the semiconductor such as a Schottky diode and so on. The large-sized solar panel apparatus 9-3 is put on the roof and so on of the automobile. To avoid the overcharge of the battery 9-1, the switch 9-5 is cut off when the automobile is not used or the enough charging is finished. When there is shortage of the charge of the battery 9-1, the switch 9-5 is switched on. It is preferable to control the charging amount by using a microcomputer. The part surrounded by the dotted line in FIG. 9 functions like the block 7-1 in FIG. 7.

FIG. 10 shows a solar apparatus of a seventh embodiment which is similar to the apparatus of FIG. 9, and so, hereinafter, differences between the apparatuses of FIGS. 9 and 10 will be mainly described. A potentiometer 10-3 and with a ground line 10-4 is provided in the part 10-9 surrounded by the dotted line. The potentiometer 10-3 is connected to the battery 10-1, a diode 10-5, and terminals 10-7, 10-8. An amount of electric voltage and current is controlled by the potentiometer 10-3 of three pole type and of the ground-type. It is preferable for the potentiometer 10-3 to handle small amount of electric power. For example, it is difficult to find a potentiometer that can be used with a battery of 70 W class. An electrical apparatus 10-6 is connected to the battery 10-1.

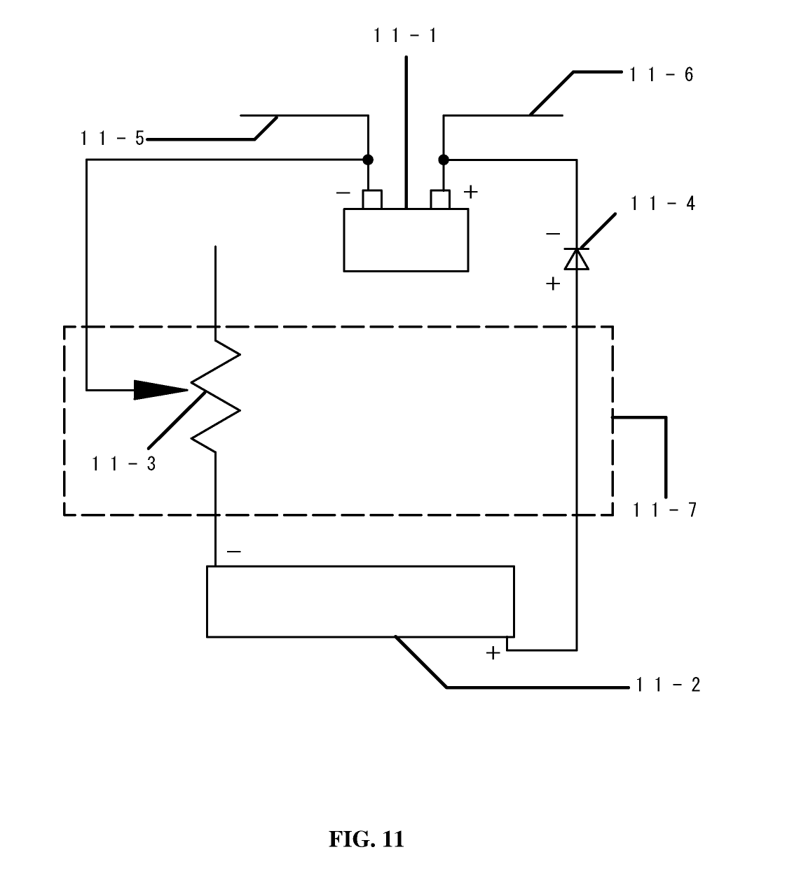

FIG. 11 shows a solar apparatus of the eighth embodiment which is similar to the apparatus of FIG. 10, and so, hereinafter, differences between the apparatuses of FIGS. 10 and 11 will be mainly described. A potentiometer 11-3, which doesn't have the ground connect, is a type of two pole, and is provided in a part 11-7 surrounded by a dotted line. Generally, a potentiometer of two pole type is more suitable to use with a large-sized solar panel than that of three pole type. To prevent the overcharge of the battery 11-1 when not using an automobile, the potentiometer 11-3 sends small amount of electric power, on the other hand, when using a automobile, it sends large amount of electric power. The reference numeral 11-5 denotes a negative terminal and 11-6 denotes a positive terminal.

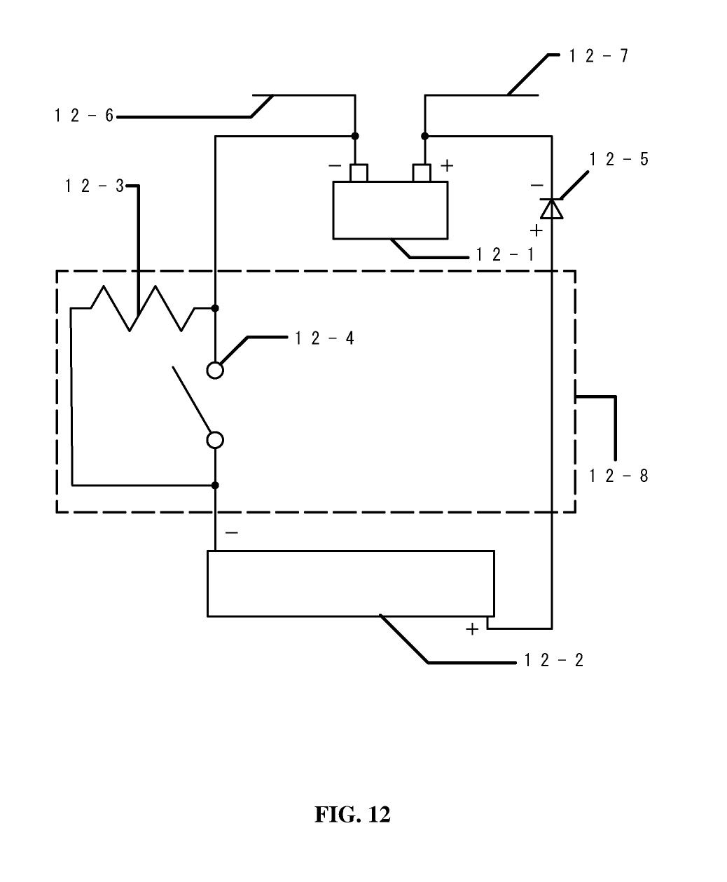

FIG. 12 shows a solar apparatus of the ninth embodiment which is similar to the apparatus of FIG. 11, and so, hereinafter, differences between the apparatuses of FIGS. 11 and 12 will be mainly described. A resistor 12-3 and an on/off switch 12-4 are provided in a part 12-8 surrounded by a dotted line. In the case the on/off switch 12-4 is open, electric current passes through the resistor 12-3. The resistance value and the maximum rating of the resistor 12-3 are set in consideration of the generation of electricity of the solar panel 12-2 and the internal resistance of the diode 12-5. When the automobile is not in use, the switch 12-4 is cut off. The resistance value of the resistor 12-3 is set so that power input from the solar panel 12-2 is between 0.01 W and 0.04 W to avoid overcharging the battery 12-1.

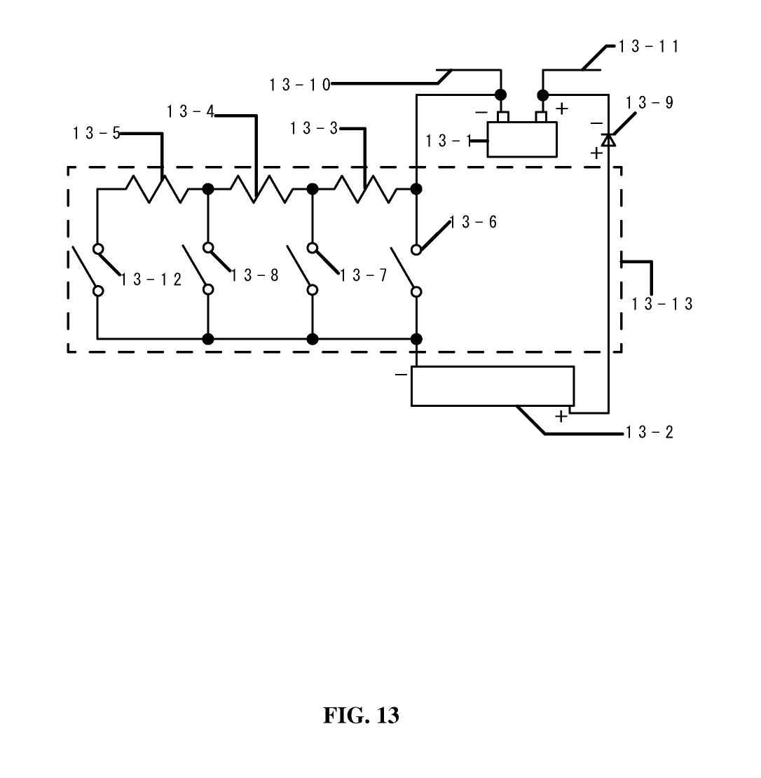

FIG. 13 shows a solar apparatus of the tenth embodiment which is similar to the apparatus of FIG. 12, and so, hereinafter, differences between the apparatuses of FIGS. 12 and 13 will be mainly described. The quantity of the electricity is adjusted according to three-step model via three resistors 13-3, 13-4, 13-5 and four on/off switches 13-6, 13-7, 13-8, and 13-12 which are provided in a part 13-13 surrounded by a dotted line. The quantity can be set to “zero”, “a few”, “medium” or “full”, for example. The resistance values and the maximum rating of the resistors 13-3, 13-4, 13-5 are set in consideration of the generation of electricity of the solar panel 13-2 and the internal resistance of the diode 13-9.

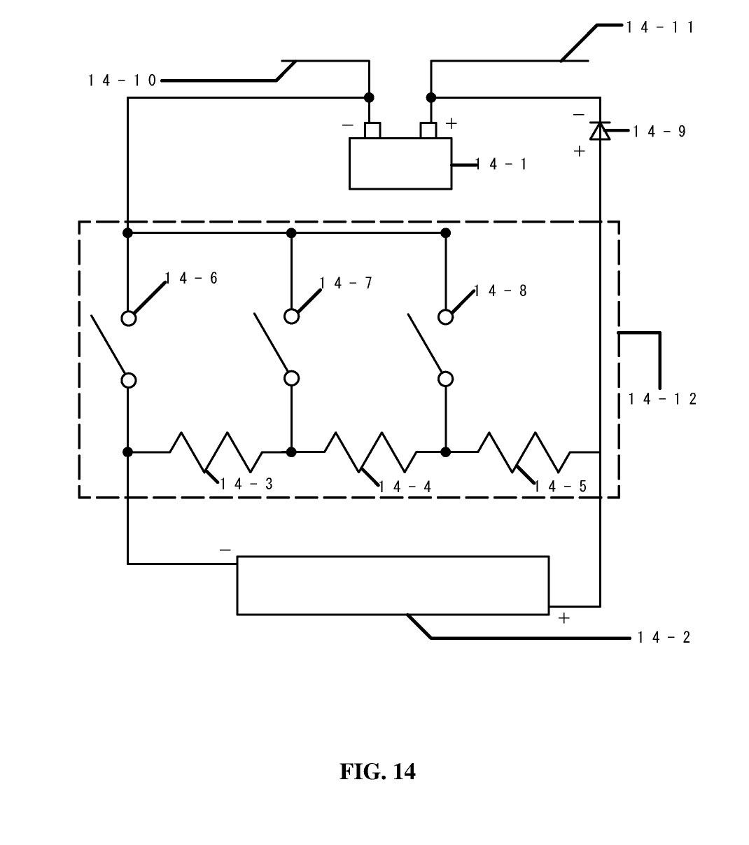

FIG. 14 shows a solar apparatus of an eleventh embodiment which is similar to the apparatus of FIG. 13, and so, hereinafter, differences between the apparatuses of FIGS. 13 and 14 will be mainly described. Resistors 14-3, 14-4, 14-5 and on/off switches 14-6, 14-7, 14-8 in parallel connection are provided in a part 14-12 surrounded by a dotted square line. They are connected as three pole type. Values of the resistors 14-3, 14-4 are greater than a value of the resistor 14-5. By selecting state of the on/off switches 14-6, 14-7 and 14-8, charge amount can be selected at three different settings: small, medium, and large.

FIG. 15 shows a solar apparatus of a twelfth embodiment which is similar to the apparatus of FIG. 9, and so, hereinafter, differences between the apparatuses of FIGS. 15 and 9 will be mainly described.

A toggle switch 15-5 is a three pole type switch. In the case that the toggle switch 15-5 is in position 15-6, the positive pole of a solar panel 15-2 is connected to a positive pole of the DC battery 15-1 so that the battery 15-1 is charged by the solar panel 15-2. When the toggle switch 15-5 is in a position 15-7, no current is conducted so that the switch is in off state. When the toggle switch 15-5 is in a position 15-8, the positive pole of the solar panel 15-2 is grounded via ground 15-9. The electric power, which is generated at the solar panel 15-2, circulates in the body metal of the automobile from the ground 15-9 to a ground 15-11, and the electric anticorrosion phenomenon occurs on the automobile body thereby improving the mileage. A negative pole of the DC-battery is provided with the ground 15-10. The ground 15-11 is preferably on the cylinder head of the gasoline engine. The position 15-7 can be deleted so that the switch 15-5 is a two pole type switch.

FIG. 16 shows a solar apparatus of the thirteenth embodiment which is similar to the apparatus of FIG. 15, and so, hereinafter, differences between the apparatuses of FIGS. 15 and 16 will be mainly described.

A toggle switch 16-5 is a three pole type switch. In the case that the toggle switch 16-5 is in a position 16-6, a positive pole of a solar panel 16-2 is connected to a positive pole of DC-battery 16-1 via a diode 16-4 so that the battery 16-1 is charged by the solar panel 16-2. When the toggle switch 16-5 is in a position 16-7, the positive pole of the solar panel 16-2 is connected to the positive pole of DC-battery 16-1 via a diode 16-13 and a relay 16-14 to which a key cylinder 16-15 is connected, so that the battery 16-1 is charged by the solar panel 16-2. When a key inserted into the key cylinder 16-15 is in a position of “ON” or “ACC”, the battery 16-1 is charged. In the case that the toggle switch 16-5 is in a position 16-8, the poles of the solar panel 16-2 are grounded via a ground 16-9 so that the electric power, which is generated at the solar panel 16-2, circulates in the body metal of the automobile from the ground 16-9 to a ground 16-11. A negative pole of the DC-battery is provided with a ground 16-10. The ground 16-11 is preferably on the cylinder head of the gasoline engine. Such a switching may be attained by computer control. The position 16-7 can be deleted so that the switch 16-5 is a two pole type switch.

FIG. 17 shows the key cylinder (ignition key cylinder) where the reference numeral 17-1 denotes a LOCK position, the reference numeral 17-2 denotes an accessory position, (“ACC”), the reference numeral 17-3 denotes the ON position (“ON”), and the reference numeral 17-4 denotes the START position.

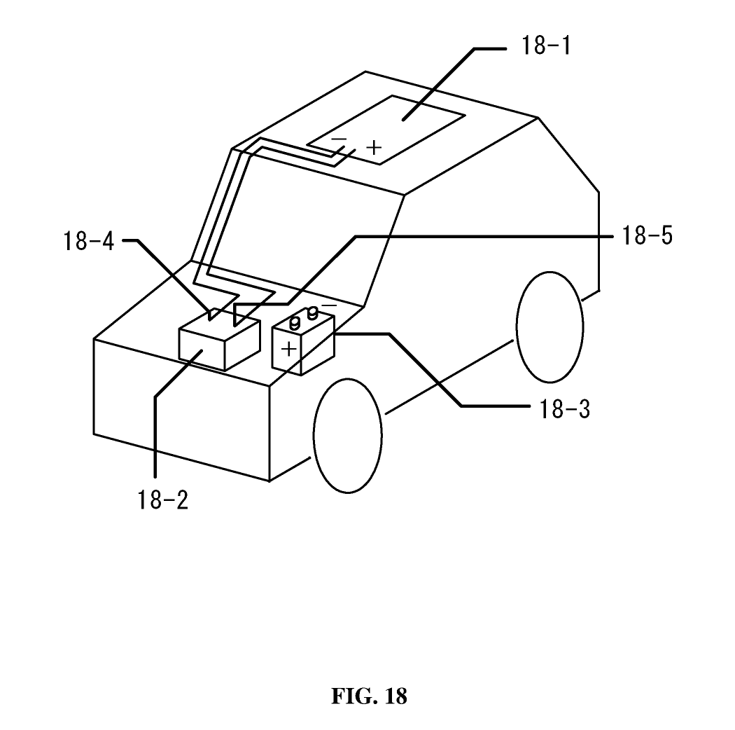

FIG. 18 shows a modified embodiment of the embodiment shown in FIG. 6. A solar panel 18-1 is provided for the purpose of electrically preventing corrosion. In FIG. 18, a positive code and a negative code from the solar panel are connected to a cylinder head of an engine 18-2. 18-4 and 18-5 indicate the points of connecting the negative code and the positive code from the solar panel to the cylinder head of the engine. However, connection to the engine cylinder head is one example. As another example, the positive code and the negative code from the solar panel may be connected respectively to two points which are located on the vehicle body in a rather short distance from each other. As another example, the codes may be connected respectively to two points which are on electrically conductive parts such as metallic parts and are electrically conductive to each other. Important thing is that these conductive parts of the vehicle are not powered by the solar panel for the purposes of light generation, heat generation, mechanical movement and the like, but are powered by the solar panel only for electric current to flow inside said conductive part of the vehicle. The effect of electric anticorrosion occurs not only when the codes from the solar panel are connected to both ends of the vehicle body but also in the cases mentioned above in this paragraph although the area where the anticorrosion effect occurs might be narrower. 18-3 indicates a battery. The battery is not connected to the solar panel in FIG. 18.

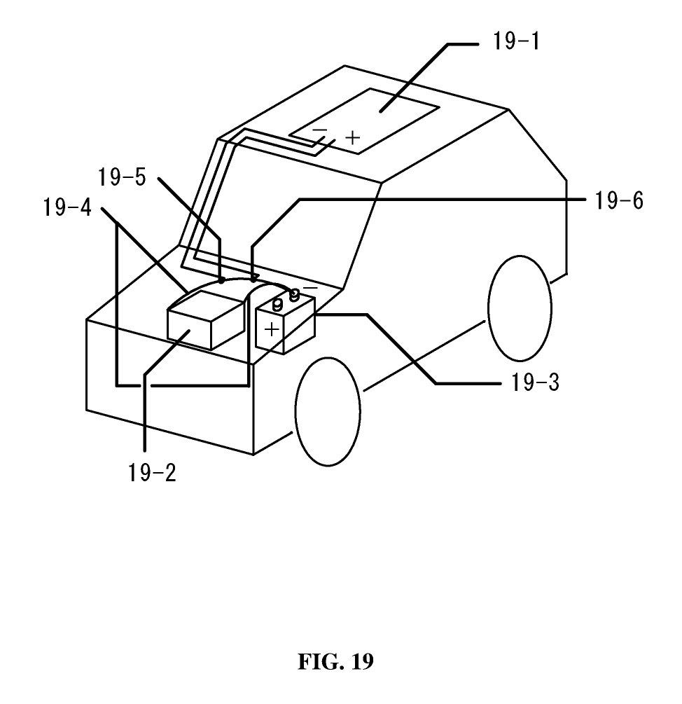

FIG. 19 shows a modified embodiment of the embodiment shown in FIG. 6. A solar panel 19-1 is provided for the purpose of electrically preventing corrosion. In FIG. 19, a positive code and a negative code from the solar panel 19-1 are connected to an earthing wire 19-4. 19-5 and 19-6 indicate the points of connecting the negative code and the positive code from the solar panel to the earthing wire 19-4. The earthing wire 19-4 is connected to a negative pole of a battery 19-3 and a cylinder head of an engine 19-2 in FIG. 19. The earthing wire 19-4 is may be connected to another equipment using body earth instead of the cylinder head of the engine. The effect of electric anticorrosion occurs also when the codes from the solar panel are connected to a code used in the vehicle such as an earthing wire.

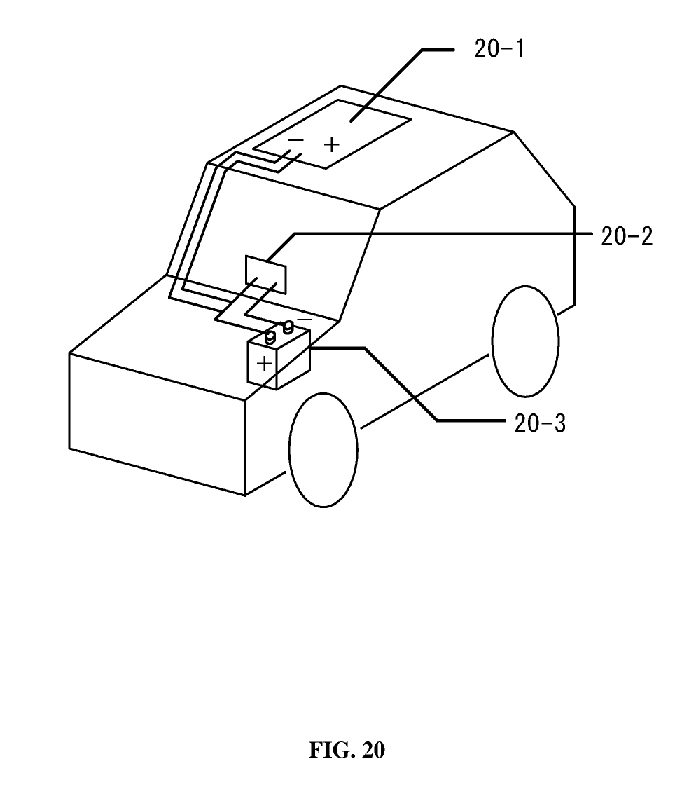

FIG. 20 shows a modified embodiment of the embodiment shown in FIG. 6. A solar panel 20-1 is provided for the purpose of electrically preventing corrosion. In FIG. 20, a positive code and a negative code from the solar panel 20-1 are connected to a conductive wire. 20-2 and 20-3 indicate the points of connecting the negative code and the positive code from the solar panel to the conductive wire. The conductive wire is connected to a battery 20-3 and equipment used in the vehicle powered by the battery. The equipment used in the vehicle may be a car navigation system, room lighting, a turbine, a heater, an electric fan, for example. The effect of electric anticorrosion occurs also when the codes from the solar panel are connected to a conductive wire for equipment used in the vehicle.

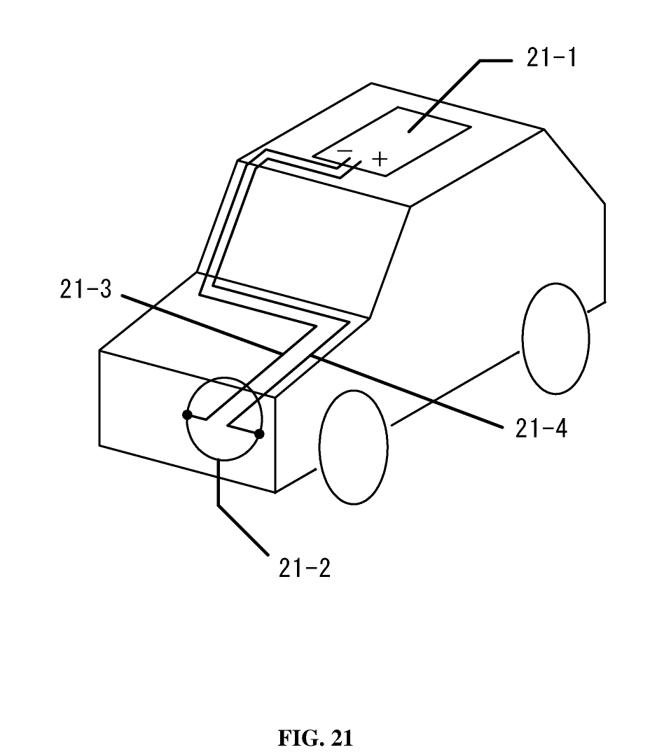

FIG. 21 shows a modified embodiment of the embodiment shown in FIG. 6. A solar panel 21-1 is provided for the purpose of electrically preventing corrosion and for supplying power to equipment. In FIG. 21, a positive code 21-4 and a negative code 21-3 from the solar panel 21-1 are connected to a fan located in front of a radiator in order to supply electric power from the solar panel to a motor of the fan. The negative code and the positive code are covered by a cover or a coating having a little conductivity in order that current leaking through the cover or the coating is circulated through conductive vehicle parts, such as the vehicle body, which have contact with the codes. The codes 21-4 and 21-3 might have leak points through which current leaks to conductive vehicle parts having contact with the codes in order that current flows through the vehicle parts. The effect of electric anticorrosion occurs also when leakage occurs from the codes to a conductive vehicle parts. Although the area to which the effect reaches is narrow, the effect would be big depending on the place. In FIG. 21, the fan of radiator is taken as an example, as it is in the water neighborhood, and possibility of leakage might be higher than other equipment. The fan 21-2 of the FIG. 21 can be exchanged for a submersible motor pump in cooling water, an air-conditioner fan or room lighting, with or without an on-off switch and with or without an microcomputer control.

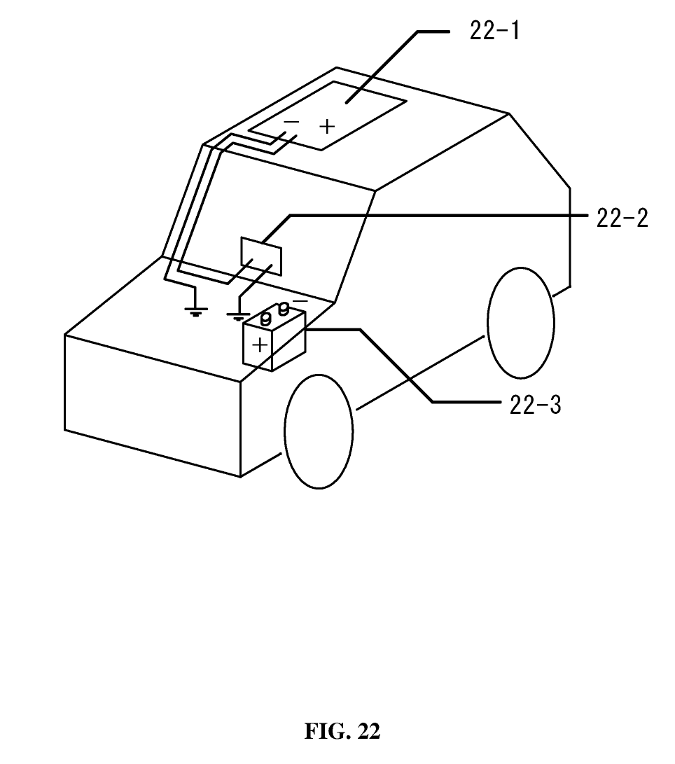

FIG. 22 shows a modified embodiment of the embodiment shown in FIG. 6. A solar panel 22-1 is provided for the purpose of electrically preventing corrosion and for supplying power to equipment. In FIG. 21, a positive code from the solar panel 22-1 is connected to the positive pole of the power terminal of a car navigation system 22-2. A negative code from the solar panel 22-1 is connected to one point on the vehicle body. A negative pole of the power terminal of a car navigation system 22-2 is connected to another point on the vehicle body. Current from the solar panel 22-1 thus flows through the vehicle body. The negative codes from the solar panel 22-1 and the positive pole of the power terminal of the car navigation system 22-2 might be connected to another conductive vehicle part so that current flows through the vehicle part. Sufficient effect of electric anticorrosion can be expected in these cases. The car navigation system 2-2 of this embodiment may be exchanged for room lighting, a turbine, a heater or an electric fan, for example. These equipments are often not connected to a car battery. Configuration described in this paragraph is suitable especially for equipments independent from a car battery.

This invention may be applied to a diesel automobile, a propane automobile, an LPG automobile, a hybrid automobile, an ambulance vehicle, an airplane, e.g., a jet airliner such as a Cessna with a similar structure as an auxiliary device of an auxiliary power unit APU, a boat and a vessel.

It is possible that smooth electricity inflow is attained and the driver need not switch an on/off switch and a toggle switch with his hand when a microprocessor controls electric power supplied by the solar panel. It is possible to adjust electric power quantity by the combination of the set of resistors and the microcomputer. A wide variety of switching features described in the various above embodiments may be controlled by a microprocessor.

While there has been described what is at present considered to be preferred embodiment of the invention, it will be understood that various modifications may be made therein, and it is intended to cover in the appended claims all such modifications as a whole within the true scope of the invention.

What is claimed is:

1. A solar-panel apparatus for a vehicle comprising:
an ignition switch;
a battery;
a solar panel; and
an electrical circuit connecting said ignition switch, said battery and said solar panel;
wherein
said electric circuit connects said battery and said solar panel when said ignition switch is in “on” or “acc” position.

2. The apparatus of claim 1, wherein said electrical circuit comprises a switch which sets an electric power input to said battery at least two settings.

3. The apparatus of claim 1, wherein
said solar-panel apparatus further comprises a second solar panel that is smaller than said solar panel, and
said second solar panel is electrically connected to said battery at all times.

4. The apparatus of claim 1, wherein an on/off switch is provided between said battery and said solar panel.

5. The apparatus of claim 1, wherein an on/off switch is provided between said battery and said solar panel, said on/off switch allowing all connections between said battery and said solar panel to be cut off if an overcharge of said battery occurs during driving, stopping, or parking.

6. The apparatus of claim 1, wherein said solar panel is provided with a switch for switching a supply state when electric output is supplied from said solar panel to said battery and a circulation state when a positive pole and a negative pole of said solar panel are connected to both ends of a body metal of said vehicle, respectively so that said solar panel functions as an electric current circulation apparatus.

7. The apparatus of claim 1, wherein
said solar-panel apparatus further comprises a second solar panel having a lower output than that of said solar panel,
an electric power which is generated at said second solar panel can be adjusted by a shutter apparatus which covers said second solar panel, or by a potentiometer or a combination of resistors which lowers said output of said second solar panel,
said second panel is always connected to said battery irrespective of said position of said ignition switch, and
said second solar panel is smaller than said solar panel.

8. A solar-panel apparatus for a vehicle comprising:
a battery;
a solar panel;
a shutter apparatus for covering said solar panel so that light input into said solar panel is adjusted; and
an electric circuit connecting said battery and said solar panel.

9. The apparatus of claim 8, further comprising a potentiometer, a resistor, or an on/off switch, or a combination thereof which lowers electricity output of said solar panel to said battery.

10. A solar-panel apparatus for a vehicle used on land, in or on the water, or in the air, including an automobile, a boat, a vessel, and an airplane, said solar-panel apparatus comprising:
a solar panel;
a conductive part of the vehicle; and
an electric circuit connecting said conductive part of the vehicle and said solar panel;
wherein
one point on said conductive part of the vehicle is connected to a positive pole of said solar panel and another point on said conductive part of the vehicle is connected to a negative pole of said solar panel so that electric current flows through said conductive part of the vehicle, and
said conductive part of the vehicle is powered by said solar panel only for electric current to flow inside said conductive part of the vehicle.

11. The apparatus of claim 10, wherein said conductive part of the vehicle is a body metal of the vehicle, a cylinder head of an engine, a grounding wire, or a conductive wire.

12. The apparatus of claim 10 further comprising an electric apparatus powered by said solar panel, wherein at least one of said two points are connected to said positive pole of the solar panel or said negative pole of the solar panel via the electric apparatus.

13. A solar-panel apparatus for a vehicle used on land, in or on the water, or in the air, including an automobile, a boat, a vessel, and an airplane, said solar-panel apparatus comprising:
a solar panel;
an electric apparatus powered by the solar panel;
a conductive part of the vehicle; and
an electric circuit connecting said solar panel and said electric apparatus powered by the solar panel;
wherein
electric leakage from said electric circuit to said conductive part of the vehicle causes electric current flowing through the conductive part of the vehicle, and
said conductive part of the vehicle is powered by said solar panel only for electric current to flow inside said conductive part of the vehicle.

14. The apparatus of claim 13, wherein said electric leakage is caused by using a code, in said circuit, covered by a coat or cover having a conductivity.

15. The apparatus of claim 13, wherein said conductive part of the vehicle is a body metal of the vehicle.
